(19) United States
(12) Patent Application Publication
(10) Pub. No.: US 2023/0290422 A1
(43) Pub. Date: Sep. 14, 2023

(54) CIRCUIT AND METHOD FOR TESTING MEMORY CHIP

(71) Applicant: CHANGXIN MEMORY TECHNOLOGIES, INC., Hefei City (CN)

(72) Inventor: Tianchen LU, Hefei (CN)

(21) Appl. No.: 17/898,516

(22) Filed: Aug. 30, 2022

Related U.S. Application Data
(63) Continuation of application No. PCT/CN2022/097887, filed on Jun. 9, 2022.

(30) Foreign Application Priority Data
Mar. 11, 2022 (CN) 202210238041.9

(51) Int. Cl. G11C 29/12

(52) U.S. Cl. CPC G11C 29/1201; G11C 2029/1202

(57) ABSTRACT

A circuit and method for testing a memory chip are provided. The circuit for testing a memory chip includes: a data reading apparatus configured to read word line data stored in all banks of a tested memory; a first comparison module, configured to receive word line data stored in one tested word line, perform a comparison test on each bit data in the word line data stored in the tested word line, and output a first test result; a second comparison module, configured to receive the first test results of all the tested word lines in one bank, and compress the first test results into a second test result; a third comparison module, configured to receive the second test result of each bank, and compress all the second test results into an N-bit final test result; and a register apparatus configured to read and save the final test result.

### CROSS-REFERENCE TO RELATED APPLICATIONS

This is a continuation of International Patent Application No. PCT/CN2022/097887, filed on Jun. 9, 2022, which claims priority to Chinese Patent Application No. 202210238041.9, filed to the China National Intellectual Property Administration on Mar. 11, 2022. International Patent Application No. PCT/CN2022/097887 and Chinese Patent Application No. 202210238041.9 are hereby incorporated by reference in their entireties.

### BACKGROUND

The memory chip, after being produced, needs to go through a series of tests such as a Chip Probe (CP) and a Final Test (FT) before it is finally ready for the market. The CP phase mainly tests a storage matrix of the memory, which is generally required to rapidly detect faulty storage cells and then repair the faulty storage cells.

### SUMMARY

The disclosure relates, but is not limited, to a circuit and method for testing a memory chip.

A first aspect of embodiments of the disclosure provides a circuit for testing a memory chip. The circuit includes a data reading apparatus, a comparison test apparatus, and a register apparatus.

The data reading apparatus is configured to read word line data stored in all banks of a tested memory, and output the word line data to the comparison test apparatus. The word line data includes a plurality of bit data.

The comparison test apparatus includes a plurality of first comparison modules, a plurality of second comparison modules, and a third comparison module that are successively connected. A number of the first comparison modules is the same as a number of tested word lines of the tested memory, and a number of the second comparison modules is the same as a number of the banks of the tested memory.

Each of the plurality of first comparison modules is configured to: receive word line data stored in a respective tested word line, perform a comparison test on each bit data in the word line data stored in the tested word line, and output a first test result.

Each of the plurality of second comparison modules is configured to: receive first test results of all tested word lines in a respective bank, and compress the first test results into a second test result.

The third comparison module is configured to receive the second test result of each bank, and compress all second test results into an N-bit final test result, N being the number of the banks of the tested memory.

The register apparatus is connected to the comparison test apparatus and configured to read and save the final test result.

A second aspect of the embodiments of the disclosure provides a method for testing a memory chip. The method includes the following operations.

Word line data stored in all banks of a tested memory is read. The word line data includes a plurality of bit data.

A comparison test is performed on each bit data in word line data stored in a tested word line, and a first test result is outputted.

The first test results of all tested word lines in a bank are compressed into a second test result.

The second test results of all banks are compressed into an N-bit final test result, where N is a number of the banks of the tested memory.

The final test result is read and saved.

A third aspect of the embodiments of the disclosure provides a non-transitory computer-readable storage medium having stored thereon an instruction that, when being executed by a processor of an electronic device, enables the electronic device to execute operations including: reading word line data stored in all banks of a tested memory, the word line data including a plurality of bit data; performing a comparison test on each bit data in word line data stored in a tested word line, and outputting a first test result; compressing first test results of all tested word lines in a bank into a second test result; compressing second test results of all banks into an N-bit final test result, where N is a number of the banks of the tested memory; and reading and saving the final test result.

### BRIEF DESCRIPTION OF THE DRAWINGS

In the drawings, unless stated otherwise, same reference signs throughout a plurality of drawings represent same or similar parts or elements. The drawings are not necessarily drawn to scale. It is to be understood that, the drawings merely describe some implementations according to the embodiments of the disclosure, and should not be considered as limiting the scope of the disclosure.

FIG. 1 is a schematic structural diagram of a circuit for testing a memory chip according to an embodiment of the disclosure.

FIG. 2 is a schematic diagram of a circuit implementation of first and second comparison modules in a circuit for testing a memory chip according to an embodiment of the disclosure.

FIG. 3 is a schematic diagram of another circuit implementation of first and second comparison modules in a circuit for testing a memory chip according to an embodiment of the disclosure.

FIG. 4 is a schematic diagram of a memory chip according to an embodiment of the disclosure.

FIG. 5A is a schematic diagram of a circuit implementation of a third comparison module according to an embodiment of the disclosure.

FIG. 5B is a schematic diagram of a circuit implementation of a third comparison module according to another embodiment of the disclosure.

FIG. 6 is an oscillogram of a simulation result during testing according to an embodiment of the disclosure.

FIG. 7 is a schematic diagram of a data path according to an embodiment of the disclosure.

FIG. 8 is a flowchart of a method for testing a memory chip according to an embodiment of the disclosure.

FIG. 9 is a schematic structural diagram of an electronic device according to an embodiment of the disclosure.

FIG. 10 is a schematic diagram of a hardware structure of an electronic device according to an embodiment of the disclosure.

### DETAILED DESCRIPTION

To make the objectives, technical solutions and advantages of the disclosure clearer, the disclosure is further described in detail below with reference to specific implementations and the drawings. It is to be understood that, these descriptions are exemplary only, and are not intended to limit the scope of the disclosure. In addition, in the following description, descriptions of well-known structures and technologies are omitted, so as to avoid unnecessary confusion of the concept of the disclosure.

It is apparent that the embodiments described herein are a part of the embodiments of the disclosure, rather than all of the embodiments. Based on the embodiments in the disclosure, all other embodiments obtained by those of ordinary skill in the art without creative work shall fall within the scope of protection of the disclosure.

Generally, a write operation defined in a JEDEC standard can only operate on one row or one column, and can only read 64 bits of data. A test machine in the CP test phase often has a low test frequency due to test items. If a read operation in a common mode is still used during the CP test phase, the reading and verification of the entire storage matrix of the memory will waste a lot of test time and consume test costs.

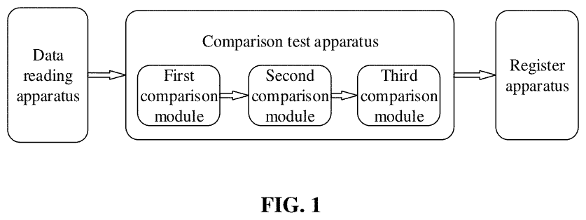

FIG. 1 is a schematic structural diagram of a circuit for testing a memory chip according to an embodiment of the disclosure.

As shown in FIG. 1, an embodiment of the disclosure provides a circuit for testing a memory chip. The circuit includes: a data reading apparatus, configured to read word line data in all of banks of a tested memory, and output the word line data to a comparison test apparatus. The comparison test apparatus is configured to receive and test the word line data in all of the banks of the tested memory, compress and output a test result with the same number of bits as the number of the banks. The test result indicates a bank where an error occurs. The word line data includes a plurality of bit data. For a row of word line data, the bit data may be 64-bit data: 8(DQ)*8 (burst length)=64-bit data. The burst length refers to the number of bits that a piece of data transmitted by DQ includes, or may be other values, such as 4 and 16, which is related to the setting of DRAM. For a memory, the bit data may be 1024-bit data. The memory includes 16 banks, and each bank has two half banks. If a word line of one of the two half banks in each bank is activated, 64*16=1024 bits, that is, 1024 bits are read at one time.

Specifically, the circuit for testing a memory chip in this embodiment provides a mode for testing the memory chip, in particular, for testing a DDR4 DRAM memory chip. A storage matrix of a memory is rapidly read by using PAGE 3 of a Multi-Purpose Register (MPR) of the memory chip. A Mode register 3 of the memory provides a MPR function. MPR PAGE 3 is not clearly defined. Values in the register may be defined by a user, so that available information may be stored and read by using the register. The use of MPR PAGE 3 may refer to Table 1. Table 1 shows MPR PAGE 3 defined by a JEDEC DDR4 standard. MPR PAGE 3 shown in Table 1 may store 32 pieces of word line information. Those skilled in the art can understand that, different memory chips have different structure designs. Therefore, the method for testing a memory chip provided in the disclosure may be implemented by using other registers in the memory chip similar to the Mode register 3.

TABLE 1
MPR PAGE3

| | MPR | | | | | | | | | |
|---|---|---|---|---|---|---|---|---|---|---|
| Address | location | [7] | [6] | [5] | [4] | [3] | [2] | [1] | [0] | Note |
| BA1:BA0 | 00 = MPR0 | don't | don't | don't | don't | don't | don't | don't | don't | |
| | | care | care | care | care | care | care | care | care | |
| | 01 = MPR1 | don't | don't | don't | don't | don't | don't | don't | don't | |
| | | care | care | care | care | care | care | care | care | |
| | 10 = MPR2 | don't | don't | don't | don't | don't | don't | don't | don't | |
| | | care | care | care | care | care | care | care | care | |
| | 11 = MPR3 | don't | don't | don't | don't | MAC | MAC | MAC | MAC | |
| | | care | care | care | care | | | | | |

(Note 1: MPR PAGE3 is specially assigned to the DRAM memory.)

During a burn in test phase of a package test, since the chip is in a high temperature and high pressure test environment, a small number of storage cells are often damaged due to some problems in a manufacturing technology. The entire storage matrix is often required to be tested after the burn in test is performed on the chip, and then an error cell is repaired. However, generally, the chip at this phase may only have problems in a few cells. Therefore, in this case, it is only required to roughly learn an error location and directly use a redundancy word line to repair the error location. In order to save test time, a compression mode provided in this embodiment may compress error information of all of cells on the entire word line into 1 bit. The compressed information is first stored in MPR page 3, and then data information in MPR page 3 is read by using an MPR READ instruction for a repairing determination. Compared with the reading of data of 2048 bits at one time by means of a read operation in the related art, the solution provided in this embodiment of the disclosure obtains only a test result with bits being equal to the number of the banks, such as 16 bits, so that the test result can be acquired more quickly, and MPR page3 of an existing register in the DRAM memory chip is used, so that an additional register is not required, thereby saving the storage space greatly.

Specifically, the comparison test apparatus may test the data by using a plurality of first comparison modules, a plurality of second comparison modules, and a third comparison module that are successively connected. The comparison modules compare each bit data in a respective word line with reference data in the MPR PAGE 0, or compare the bit data in each bank in order. When there is a difference between the compared data, an output error level TEOROT is valid. That is to say, the comparison modules may adopt two modes to compare the data, which are an EXP mode and an EOR mode. In a comparison read mode, an ACT CMD instruction may activate the word lines in 16 banks. One bank is divided into two half banks. Each half bank activates one word line, that is, the 16 banks totally activate 32 word lines. The read operation in the compression mode compares each bit data in a data input/output channel with the reference data in the MPR PAGE 0, for example, performing mutual exclusive-OR comparison, to obtain the comparison result, and this comparison mode is usually called the “EXP mode”. Alternatively, the bit data in adjacent data input/output channels may be compared in order, for example, performing mutual exclusive-OR comparison, to obtain the comparison result, and this mode is usually called the “EOR mode”. If there is a difference between the compared data, it is indicated that there is a problem in the cell, and the output error level TEOROT signal is at a high level.

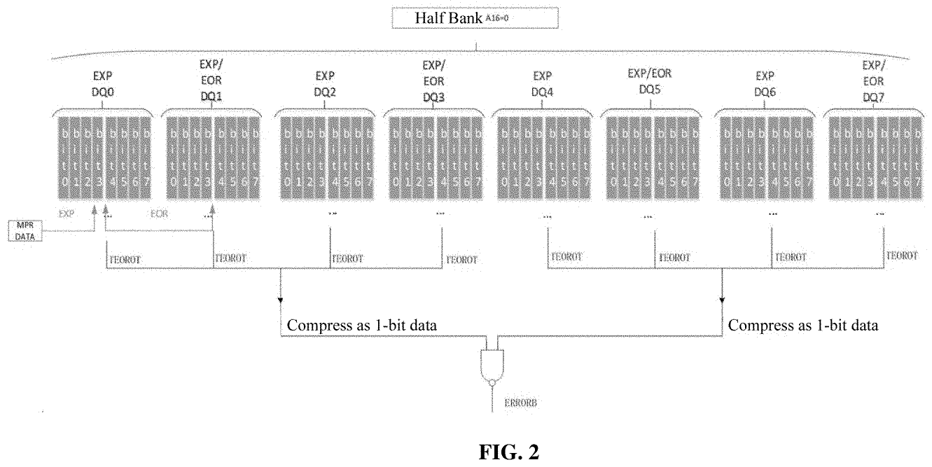

FIG. 2 is a schematic diagram of a circuit implementation of a first comparison module and a second comparison module.

The first comparison module is configured to receive a word line data stored in a respective tested word line, perform a comparison test on each bit data in the word line data stored in the respective tested word line, and output a first test result TEOROT. As shown in FIG. 2, a half bank is used as an example. For the data stored in the tested word line included in the half bank, the data read in a single read operation is transmitted through 8 data input/output channels, that is, the data input/output channel 0 to the data input/output channel 7 (DQ0 to DQ7). The first comparison module compares the data of the 8 data input/output channels. Each of the data input/output channel 0 to the data input/output channel 7 corresponds to 8-bit data, i.e., bit0 to bit7.

In an example, the first comparison module includes a plurality of exclusive-OR gates. Input ends of each exclusive-OR gate are connected to a bit data in the word line data stored in the tested word line and the reference data. A circuit of the first comparison module has two sets of input ends. During data mutual exclusive-OR comparison (the EXP mode), bit data in the 8 data input/output channels is inputted into one set of input ends, and the reference data pre-stored in MPR DATA (that is, the data in the MPR page0) is inputted into the other set of input ends. Then, each bit data is compared with the reference data. That is to say, each bit data in the data input/output channel 0 to the data input/output channel 7 is compared with the reference data. In another example, the first comparison module includes a plurality of exclusive-OR gates. Input ends of each exclusive-OR gate are connected to two bit data in the word line data stored in the tested word line. The first comparison module is further configured to pairwise compare the bit data, corresponding to different data input/output channels, in the word line data stored in the tested word line. A respective first test result is output for each bit data. When any bit data in the word line data stored in the tested word line is different from the reference data, or when any two bit data in the word line data stored in the tested word line is different, the first test result TEOROT is an error level.

Specifically, when sequential comparison (the EOR mode) is adopted, each bit data in one of the 8 data input/output channels is inputted into one set of input ends, and each bit data in another data input/output channel is inputted into the other set of input ends. Then, the two sets of data are compared in order. For example, the data in the data input/output channel 0 and the data in the data input/output channel 1 are successively compared, the data in the data input/output channel 2 and the data in the data input/output channel 3 are successively compared, the data in the data input/output channel 4 and the data in the data input/output channel 5 are successively compared, the data in the data input/output channel 6 and the data in the data input/output channel 7 are successively compared, so as to obtain the comparison results. The inputted data of the data input/output channels is derived from the word line data in all of the banks of the tested memory that is read by a data reading apparatus.

When the comparison result is that the two data are inconsistent, the circuit of the first comparison module outputs the error level, that is, the first test result TEOROT is valid. Then the first test result TEOROT is outputted to the second comparison module.

In some embodiments, different comparison modes may be applied to the data in different data input/output channels. As shown in FIG. 2, the EXP mode may be applied to the data in DQ0, DQ2, DQ4, and DQ6 for comparison, and the EXP mode or the EOR mode may be applied to the data in DQ1, DQ3, DQ5, and DQ7 for comparison. By means of a combination of different comparison modes, the accuracy of the comparison results is further enhanced.

A circuit of the second comparison module merges the first test result TEOROT of each bit of each data input/output channel, and then outputs a second test result ERRORB. The number of bits of the first test result TEOROT is the same as that of the bit data for comparison. For example, the 64-bit first test result TEOROT is outputted after the 64-bit data is compared in FIG. 2. When any of the first test results TEOROT reports an error, the second test result ERRORB reports an error.

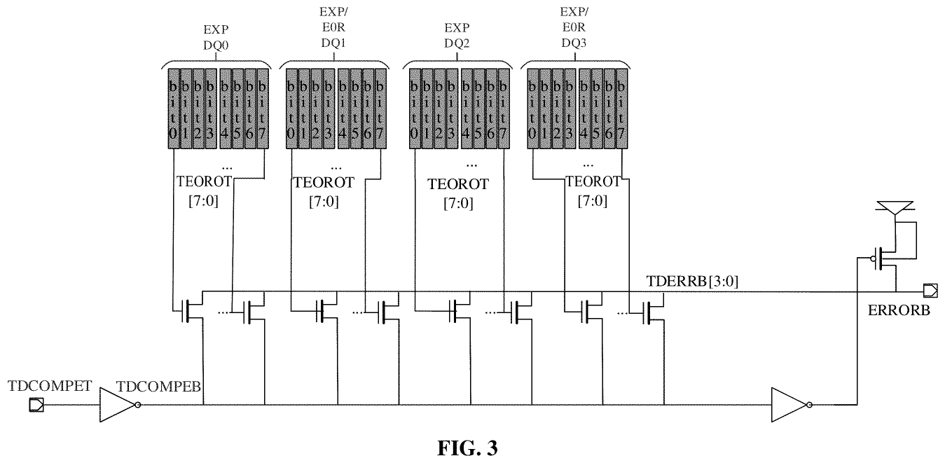

FIG. 3 is a schematic diagram of another circuit implementation of a first comparison module and a second comparison module.

As shown in FIG. 3, the second comparison module includes a plurality of NMOS transistors. A control end of each NMOS transistor is connected to a first test result TEOROT. An input end of the NMOS transistor is connected to a first level, and an output end of the NMOS transistor is configured to output a second test result ERRORB. The second comparison module includes a pre-charging module. The pre-charging module is configured to pre-charge the output end to a second level. The pre-charging module includes an inverter and a PMOS transistor. An output end of the inverter is connected to a control end of the PMOS transistor. An output end of the PMOS transistor is connected to the output end of the NMOS transistor, and an input end of the PMOS transistor is connected to the second level.

In some embodiments, the 64-bit data of the 8 data input/output channels may be merged by using 64 NMOS transistors, and are directly compressed into 1-bit second test result ERRORB. Alternatively, the data of part of the input/output channels may be merged by using a plurality of NMOS transistors, and then the resulting data is operated by using an AND gate or a NAND gate, to obtain the 1-bit second test result ERRORB. For example, as shown in FIG. 2, the data of DQ0 to DQ3 is compressed into 1-bit data by using 32 NMOS transistors, and the data of DQ4 to DQ7 is compressed into 1-bit data by using 32 NMOS transistors. Then, the two pieces of 1-bit data are operated by using the NAND gate, to obtain the second test result ERRORB.

Exemplarily, the first level is a high level, and the second level is a low level. The first level may also be the low level, and the second level may be the high level, which may be set according to actual requirements. For example, when the first test result TEOROT is the high level, it represents that there is an error in the corresponding bit data of the data input/output channel. Then, the first test results TEOROT of the data input/output channel 0 to the data input/output channel 3 are directly wired-AND, and the first test results TEOROT of the data input/output channel 4 to the data input/output channel 7 are directly wired-AND. Then, the resulting two 1-bit results are inputted into the NAND gate to obtain the second test result ERRORB. That is to say, the comparison result of the half bank is obtained, which is a 1-bit data. When the second test result ERRORB is the high level, it indicates that there is an error data in the corresponding bank. When the second test result ERRORB is the low level, it indicates that there is no error in the data in the corresponding bank. As long as the comparison result of any bit in the data input/output channel represents an error, the outputted result reports an error after data compression, so that data storage space can be saved, and the error bank can also be rapidly located.

As shown in FIG. 3, TDCOMPET in the figure indicates an instruction of a comparison operation, which is at the low level during pre-charging and at the high level during comparison operation. TDCOMPEB is an inverted signal of TDCOMPET. After the data of each data input/output channel is compared, a 8-bit TEOROT signal is outputted as the comparison result. The comparison may adopt the EXP mode or the EOR mode. When the comparison result of any bit data in the data input/output channel is different, the corresponding TEOROT signal outputs the high level. FIG. 3 shows an embodiment of a comparison circuit for comparing data. Data comparison may also be implemented by using other comparison circuits, which is not limited herein. Exemplarily, the second comparison module includes a plurality of NMOS transistors. A control end of each NMOS transistor is connected to a respective first test result TEOROT. An input end of the NMOS transistor is connected to a first level, and an output end of the NMOS transistor is configured to output a second test result ERRORB. The second comparison module includes a pre-charging module. The pre-charging module is configured to pre-charge the output end to a second level. The pre-charging module includes an inverter and a PMOS transistor. An output end of the inverter is connected to a control end of the PMOS transistor. An output end of the PMOS transistor is connected to the output end of the NMOS transistor. An input end of the PMOS transistor is connected to the second level. In a non-compression mode, the low level is inputted, the PMOS transistor is turned on, and then the output end is pre-charged to the high level. In a compression mode, the high level is inputted, and the PMOS transistor is turned off. If any of the NMOS transistors is turned on (that is, if there is an error level), the output end is pulled down to the low level. During this comparison operation, the second comparison module compresses the TEOROT signals outputted by the respective data input/output channels into an error comparison result signal ERRORB to output. The error comparison result signal ERRORB indicates whether the bank has an error test result. As long as a comparison result of one bit in the data input/output channels in the bank represented by the error comparison result signal ERRORB is wrong, the final error comparison result signal ERRORB reports an error, indicating that there is an error in the bank, and a 1-bit final comparison result is outputted.

The comparison module is further configured to merge the comparison result of each bank, and outputs a total comparison result with the same number of bits as the number of the banks. The total comparison result indicates the bank where the error occurred. DRAM memory i.e., DDR4 includes 16 banks, that is, 32 half banks. One piece of word line data of the tested word line in each half bank is read in each read operation, that is, a total of 32 pieces of word line data is read. After the read data is compressed by the first comparison module and the second comparison module, the data stored in each word line is compressed into the 1-bit comparison result. That is to say, a 32-bit total comparison result will be output for the 16 banks.

The third comparison module is configured to receive the second test result ERRORB of each bank, and merge all of the second test results ERRORB into an N-bit final test result, where N is the number of the banks in the tested memory. For example, the 32-bit second test result ERRORB outputted by the second comparison module is compressed into a 16-bit final test result. Two second test results ERRORB corresponding to a bank are inputted into the AND gate or the NAND gate for operation, so as to output the 1-bit final test result corresponding to the bank.

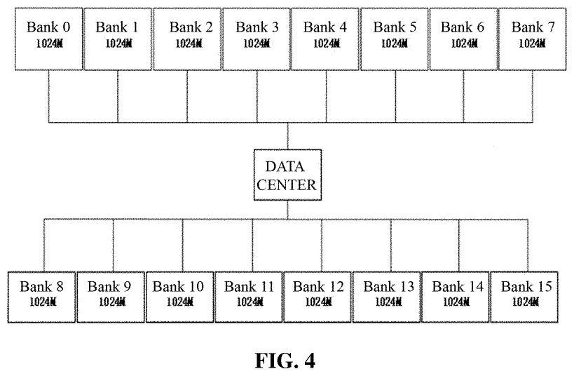

FIG. 4 is a schematic diagram of a memory. In this embodiment, the memory totally has 16 banks, and each bank is connected to a data center. The 1-bit comparison result is output for each bank. The third comparison module performs data merging on 16 1-bit second test results ERRORB and locations corresponding to the 16 banks, so as to obtain the 16-bit final test result. For example, in the final test result, starting from a low bit, the 1st bit represents the test result of the bank 0, the 2nd bit represents the test result of the bank 1, . . . , the 16th bit represents the test result of the bank 15. The 16-bit final test result is inputted into the data center, to perform data processing and data transmission on the final test result by means of the data center.

The comparison test apparatus of the disclosure may further include a test result output module. The test result output module is connected to the data center. When a compression enable signal is valid, the total comparison result outputted by the comparison module is read and outputted to the MPR. The total comparison result of one comparison is obtained per reading. The test result output module may be further configured to output an error data signal. When a storage matrix with an error is read in the total comparison result at a certain time, the error data signal is valid until the signal is reset.

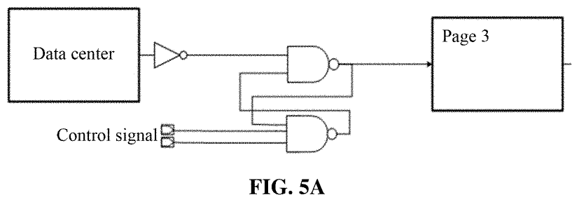

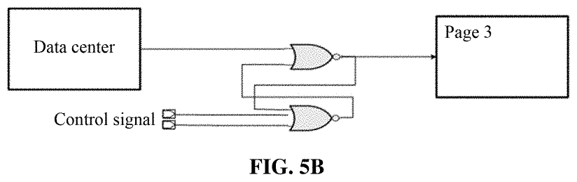

As shown in FIG. 5A and FIG. 5B, an output end of the data center is connected to the test result output module, and the final test result is inputted into the test result output module. A control signal is input into the test result output module. The control signal includes the compression enable signal and/or an activate command and/or a pre-charging command. An output end of the test result output module is connected to the MPR PAGE 3 of the memory chip.

In an example, as shown in FIG. 5A, the third comparison module includes a NOT gate and a first SR latch. The first SR latch includes a first NAND gate and a second NAND gate. A first input end of the first NAND gate is configured to input the second test result, and an output end of the first NAND gate is connected to a register apparatus and is connected to a second input end of the second NAND gate. A first input end of the second NAND gate is configured to input a control signal, and an output end of the second NAND gate is connected to a second input end of the first NAND gate. For example, the control signal is at a low level. Under normal conditions, the second test result outputs a high level, which becomes a low level after the NOT gate, and then the first NAND gate outputs a high level all the time. Under abnormal conditions, the second test result outputs a low level, which becomes a high level after the NOT gate, and then the first NAND gate outputs a low level. Therefore, once the low level is found in the register apparatus, an existence of abnormal data can be determined.

In another example, as shown in FIG. 5B, the third comparison module includes a second SR latch. The second SR latch includes a first NOR gate and a second NOR gate. A first input end of the first NOR gate is configured to input the second test result, and an output end of the first NOR gate is connected to the register apparatus and is connected to a second input end of the second NOR gate. A first input end of the second NOR gate is configured to input the control signal, and an output end of the second NOR gate is connected to a second input end of the first NOR gate. For example, the control signal is at the high level. Under normal conditions, the second test result outputs a high level, and then the first NOR gate outputs a low level all the time. Under abnormal conditions, the second test result outputs a low level, and then the first NOR gate outputs a high level. Therefore, once the high level is found in the register apparatus, the existence of the abnormal data can be determined.

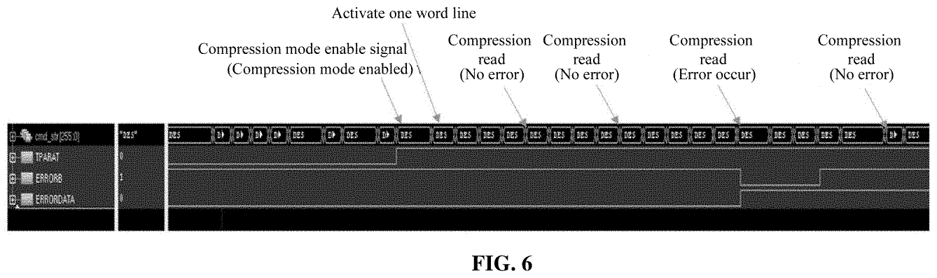

FIG. 6 is an oscillogram of a simulation result during testing by using the solution in the embodiment.

As shown in FIG. 6, when a compression mode signal is valid, it indicates that the compression mode is started. In this case, the test result data is started to be read out. FIG. 6 further shows data waveforms when an error occurs and when no error occurs during the compression mode for reading. When an error occurs, an error comparison result signal becomes the low level, and the outputted error data signal becomes the high level. In addition, the outputted error data signal continuously remains the high level, until a command is used to reset the signal.

Through the solution provided in this embodiment, when the memory chip is tested, a word line of each of the banks may be activated at one time, and all data on the word line is continuously read out. Then, the read data is stored in the MPR Page3. The data is then read out by means of an existing MPR read function, for example, an MPR reading apparatus. Therefore, which word line has an error may be rapidly known, and then the word line is repaired.

Test information stored in the MPR Page3 may be shown in Table 2.

As shown in Table 2, the MPR Page3 may totally store PAGE information of 32 word lines. Each bit of the MPR Page3 may store test result information of a first word line or a second word line representing each of the 16 banks. Therefore, great convenience can be provided for a tester to address the error bank.

TABLE 2
Test information stored in MPR Page3

| | MPR | | | | | | | | | |
|---|---|---|---|---|---|---|---|---|---|---|
| Address | location | [7] | [6] | [5] | [4] | [3] | [2] | [1] | [0] | note |
| BA1:BA0 | 00 = MPR0 | 1^{st}WL | 1^{st}WL | 1^{st}WL | 1^{st}WL | 1^{st}WL | 1^{st}WL | 1^{st}WL | 1^{st}WL | |
| | | bank0 | bank1 | bank2 | bank3 | bank4 | bank5 | bank6 | bank7 | |
| | 01 = MPR1 | 1^{st}WL | 1^{st}WL | 1^{st}WL | 1^{st}WL | 1^{st}WL | 1^{st}WL | 1^{st}WL | 1^{st}WL | |
| | | bank8 | bank9 | bank10 | bank11 | bank12 | bank13 | bank14 | bank15 | |
| | 10 = MPR2 | 2^{nd}WL | 2^{nd}WL | 2^{nd}WL | 2^{nd}WL | 2^{nd}WL | 2^{nd}WL | 2^{nd}WL | 2^{nd}WL | |
| | | bank0 | bank1 | bank2 | bank3 | bank4 | bank5 | bank6 | bank7 | |
| | 11 = MPR3 | 2^{nd}WL | 2^{nd}WL | 2^{nd}WL | 2^{nd}WL | 2^{nd}WL | 2^{nd}WL | 2^{nd}WL | 2^{nd}WL | |
| | | bank8 | bank9 | bank10 | bank11 | bank12 | bank13 | bank14 | bank15 | |

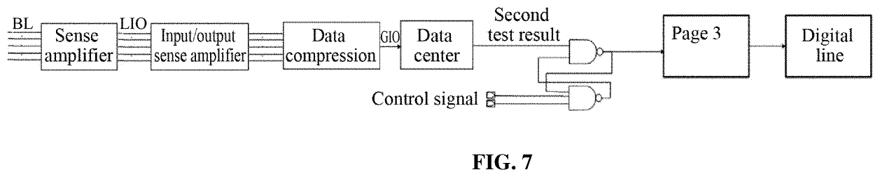

FIG. 7 is a schematic diagram of a data path according to an embodiment of the disclosure.

As shown in FIG. 7, Bit Line (BL) data connected to a storage cell in the memory is amplified by a Sense Amplifier (SA), and outputted to a Local Input/Output (LIO) line. The data of the LIO line passes through an Input/Output Sense Amplifier (IOSA), and is outputted to a General Input/Output (GIO) line after data compression. Then, the data enters the data center for processing.

In the test compression mode used by the test circuit provided in the embodiments, a conventional DDR4 functional circuit and a Design For Test (DFT) circuit are combined. Therefore, an area required for the test circuit can be reduced. In addition, the compression mode may be used for some special test requirements. In particular, for example, in the burn in test, when there are only several bit fails in the entire storage matrix, the error word line may be rapidly found for repairing.

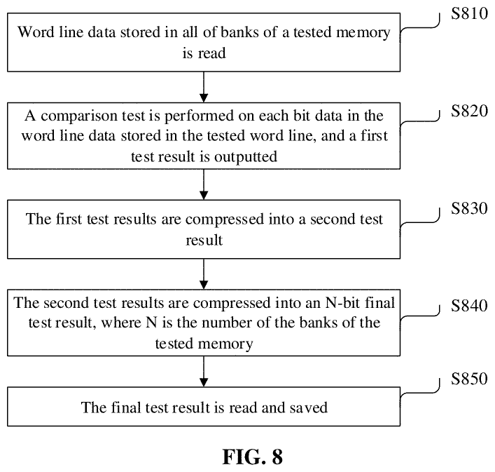

Another embodiment of the disclosure provides a method for testing a memory chip. A flowchart of the test method is shown in FIG. 8. The method includes the following operations.

At S810, word line data stored in all of banks of a tested memory is read. The word line data includes a plurality of bit data.

At S820, a comparison test is performed on each bit data in the word line data stored in a tested word line, and a first test result is outputted.

At S830, the first test results are compressed into a second test result.

At S840, the second test result is compressed into an N-bit final test result, where N is the number of the banks of the tested memory.

At S850, the final test result is read and saved.

The testing of the data may adopt the following two manners.

The first manner includes: acquiring reference data; and comparing each bit data in the word line data stored in the tested word line with the reference data. When any bit data in the word line data stored in the tested word line is different from the reference data, the first test result is at an error level. That is, the EXP mode is adopted. The read operation in the compression mode performs mutual exclusive-OR comparison on each bit in the data input/output channel and the data stored in the MPR page0, so as to obtain the comparison result.

The second manner includes: pairwise comparing the bit data, corresponding to different data input/output channels, in the word line data stored in the tested word line. When any two bit data in the word line data stored in the tested word line are different, the first test result is at an error level. That is the EOR mode is adopted. The bit in the data input/output channel 0 is compared with the bit in the data input/output channel 1 in order, so as to obtain the comparison result.

When the EXP mode is used for comparison, mutual exclusive-OR comparison may be performed on each bit in the data input/output channel and MPR DATA (that is, data stored in the MPR page0). When the EOR mode is used for comparison, the bit in the data input/output channel 0 is compared with the bit in the data input/output channel 1 in order, so as to obtain the comparison result. The comparison results of all bits of the data input/output channels are merged, for example, by performing an exclusive OR operation on the comparison results, and the obtained result may be compressed again for output. As long as the comparison result of any bit of the data input/output channel is wrong, the outputted result reports an error, that is, the outputted error level is valid.

In each bank, when any bit of the data input/output channel is error and the outputted error level is valid, the outputted error comparison result signal is valid. The signals outputted by respective data input/output channels are compressed into the error comparison result signal to output. As long as the bit comparison result of one of the data input/output channels is wrong, the final error comparison result signal reports an error, and a 1-bit final comparison result is outputted.

Then, the comparison results of all banks are merged, and a total comparison result with the same number of bits as the number of the banks is outputted. The total comparison result indicates the error bank. The memory chip DDR4 totally has 16 banks, the total comparison result is 16-bit data, and each bit indicates whether there is an error in the bank represented by the bit.

When a compression enable signal is valid, the total comparison result is read and outputted to the MPR. The total comparison result of one comparison is obtained at each reading. An error data signal is further outputted. When an error bank is read in the final test result at a certain time, the outputted error data signal remains valid, until the signal is reset. The compressed test result is read and saved by the MPR PAGE3.

Finally, the error bank is found by reading the test result stored in the MPR, and the error bank is repaired.

To sum up, the disclosure provides a circuit and method for testing a memory chip. By using the compression test mode and a reserved register, i.e., the MPR in the memory, a rapid read operation is performed on the storage matrix of the memory by using the MPR PAGE3 of the memory chip, so as to test the memory chip. Then, the test results are further compressed after testing, and a final test result with the same number of bits as the number of the banks of the memory chip is outputted. The test result may indicate the location of the error bank in the DARM chip. In the disclosure, the functional circuit of the memory DDR4 chip is used and combined with the DFT circuit, so that the area required for implementing the test functional circuit can be reduced. Moreover, the error location can be found more quickly. In the disclosure, test efficiency is enhanced by using the reserved MPR PAGE3 of the memory chip and the freedom in the test mode of the memory. Therefore, the disclosure is applicable to memory engineering analysis tests and mass production tests.

It is to be understood that, the above specific implementations of the disclosure are merely used to illustrate or explain the principles of the disclosure, and not intended to limit the disclosure. Therefore, any modifications, equivalent replacements, improvements and the like made without departing from the spirit and scope of the disclosure shall fall within the scope of protection of the disclosure. In addition, the appended claims of the disclosure are intended to cover all changes and modifications that fall within the scope and boundaries of the appended claims or the equivalents of such scope and boundaries.

Operations in the method of the embodiments of the disclosure may be adjusted in order, merged and deleted according to actual requirements. The modules in the circuit of the embodiments of the disclosure may be merged, divided and deleted according to actual requirements.

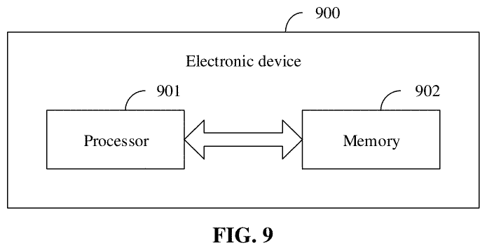

Optionally, as shown in FIG. 9, an embodiment of the disclosure further provides an electronic device 900, including a processor 901 and a memory 902 having stored thereon a program or an instruction executable by the processor 901. The program or the instruction, when being executed by the processor 901, causes the processor 901 to implement each process of the embodiment of the method for testing a memory chip, and the same technical effect can be achieved. In order to avoid repetition, details are not described herein again.

It is to be noted that, the electronic device in this embodiment of the disclosure includes the above mobile electronic device and a non-mobile electronic device.

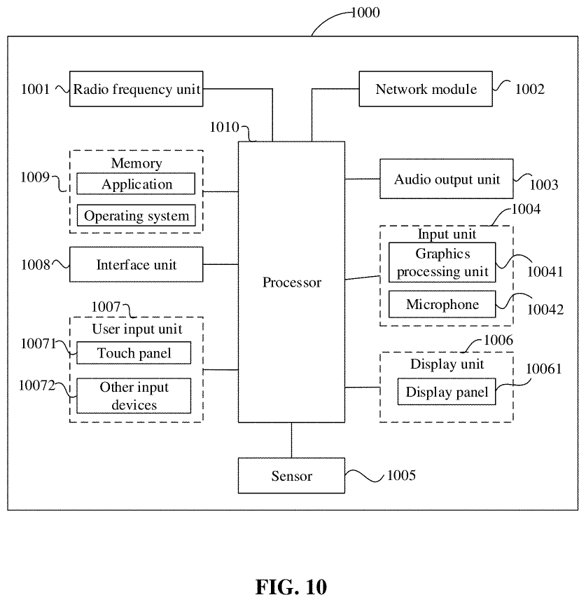

FIG. 10 is a schematic diagram of a hardware structure of an electronic device according to an embodiment of the disclosure.

The electronic device 1000 includes, but is not limited to, a radio frequency unit 1001, a network module 1002, an audio output unit 1003, an input unit 1004, a sensor 1005, a display unit 1006, a user input unit 1007, an interface unit 1008, a memory 1009, a processor 1010, and the like.

It may be understood by those skilled in the art that, the electronic device 1000 may further includes a power supply (such as a battery) for supplying power for each component. The power supply may be logically connected to the processor 1010 by means of a power management system, so that functions such as charging management, discharging management, and power consumption management can be implemented by means of the power management system. A structure of the electronic device shown in FIG. 10 does not constitute a limitation to the electronic device. The electronic device may include more or less components than that shown in the figure, or combine some components, or arrange different components, and will not be elaborated herein again.

It is to be understood that, in this embodiment of the disclosure, the input unit 1004 may include a Graphics Processing Unit (GPU) 10041 and a microphone 10042. The GPU 10041 processes a static picture or image data of a video obtained by an image capture device (for example, a camera) in a video capture mode or an image capture mode. The display unit 1006 may include a display panel 10061. The display panel 10061 may be configured in the form of a liquid crystal display, an organic light emitting diode, or the like. The user input unit 1007 includes a touch panel 10071 and other input devices 10072. The touch panel 10071 is also called a touch screen. The touch panel 10071 may include a touch detection device and a touch controller. Other input devices 10072 may include, but are not limited to, a physical keyboard, a function key (such as a volume control button, a switch button, or the like), a trackball, a mouse, and a joystick, which are not described herein again. The memory 1009 may be configured to store a software program and various data, including, but not limited to, an application and an operating system. The processor 1010 may integrate an application processor and a modem processor. The application processor mainly processes the operating system, a user interface, and the application. The modem processor mainly processes wireless communication. It is to be understood that, the modem processor may also not be integrated into the processor 1010.

An embodiment of the disclosure further provides a readable storage medium having stored therein a program or an instruction that, when being executed by a processor, causes the processor to implement each process of the method for testing a memory chip, and the same technical effect can be achieved. In order to avoid repetition, details are not described herein again.

The processor is the processor in the electronic device described in the above embodiment. The readable storage medium includes a computer-readable storage medium, for example, a Read-Only Memory (ROM), a Random Access Memory (RAM), a magnetic disk, or an optical disk.

It is to be noted that terms “include” and “comprise” or any other variant thereof is intended to cover nonexclusive inclusions herein, so that a process, method, object or apparatus including a series of elements not only includes those elements but also includes other elements which are not clearly listed or further includes elements intrinsic to the process, the method, the object or the apparatus. In the absence of more limitations, an element defined by the statement “including a/an . . . ” does not exclude existence of the other same elements in a process, method, object or apparatus including the element. In addition, it is to be noted that, the method and apparatus in the embodiments of the disclosure is not limited to performing the functions in a shown or discussed order, and may also include performing the functions in a substantially simultaneous manner or in a reverse order depending on the functions involved. For example, the method may be executed in an order different from that described herein, and various steps may also be added, omitted, or combined. In addition, features described with reference to some examples may be combined in other examples.

From the above descriptions about the embodiments, those skilled in the art will clearly know that the method in the foregoing embodiments may be implemented in a manner of combining software and a necessary universal hardware platform, and may also be implemented through hardware, but the former is a preferred implementation mode under many circumstances. Based on such an understanding, the technical solutions of the disclosure substantially or parts making contributions to the related art may be embodied in form of a computer software product, and the computer software product is stored in a storage medium (for example, a ROM/RAM, a magnetic disk or an optical disk), including a plurality of instructions configured to enable a terminal (which may be a mobile phone, a computer, a server, a network device, or the like) to execute the method in each embodiment of the disclosure.

The embodiments of the disclosure are described above with reference to the accompanying drawings, but the disclosure is not limited to the above specific embodiments, which are merely illustrative rather than restrictive. Under the inspiration of the disclosure, those of ordinary skill in the art can also make many forms without departing from the scope of the disclosure and the protection scope of the claims, which all fall within the scope of protection of the disclosure.

Further, it should be noted that the modules or units in the circuit for testing a memory chip according to the embodiments of the disclosure, for example, the first comparison module, the second comparison module, the third comparison module and the pre-charging module, can be implemented by circuits.

The disclosure provides the circuit and method for testing a memory chip. The circuit for testing a memory chip includes a data reading apparatus, a first comparison module, a second comparison module, a third comparison module and a register apparatus. The data reading apparatus is configured to read word line data stored in all of banks of a tested memory. The first comparison module is configured to receive the word line data stored in one tested word line, perform the comparison test on each bit data in the word line data stored in the tested word line, and output a first test result. The second comparison module is configured to receive the first test results of all of the tested word lines in one bank, and compress the first test results into a second test result. The third comparison module is configured to receive the second test result of each bank, and compress all of the second test results into an N-bit final test result. The register apparatus is configured to read and save the final test result. Through the test circuit, an area required for implementing a test functional circuit can be reduced, and an error location can be found more quickly.

1. A circuit for testing a memory chip, comprising:
a data reading apparatus, configured to read word line data stored in all banks of a tested memory, and output the word line data to a comparison test apparatus, wherein the word line data comprises a plurality of bit data;
the comparison test apparatus, comprising a plurality of first comparison modules, a plurality of second comparison modules, and a third comparison module that are successively connected; a number of the first comparison modules is the same as a number of tested word lines of the tested memory, and a number of the second comparison modules is the same as a number of the banks of the tested memory; wherein
each of the plurality of first comparison modules is configured to: receive word line data stored in a respective tested word line, perform a comparison test on each bit data in the word line data stored in the tested word line, and output a first test result;
each of the plurality of second comparison modules is configured to: receive first test results of all tested word lines in a respective bank, and compress the first test results into a second test result; and
the third comparison module is configured to receive the second test result of each bank, and compress all second test results into an N-bit final test result, N being the number of the banks of the tested memory; and
a register apparatus, connected to the comparison test apparatus and configured to read and save the final test result.

2. The circuit of claim 1, further comprising a multipurpose register configured to store reference data; wherein
each of the plurality of first comparison modules comprises a plurality of exclusive-OR gates, and input ends of each exclusive-OR gate are connected to a respective bit data in the word line data stored in the tested word line and the reference data, respectively; and
each of the plurality of first comparison modules is further configured to: compare the bit data in the word line data stored in the tested word line with the reference data, and when any bit data in the word line data stored in the tested word line is different from the reference data, output an error level as the first test result.

3. The circuit of claim 1, wherein each of the plurality of first comparison modules comprises a plurality of exclusive-OR gates, and input ends of each exclusive-OR gate are connected to two bit data in the word line data stored in the tested word line, respectively;
each of the plurality of first comparison modules is further configured to: pairwise compare bit data, corresponding to different data input/output channels, in the word line data stored in the tested word line, and when any two bit data in the word line data stored in the tested word line are different, output an error level as the first test result.

4. The circuit of claim 1, wherein each of the plurality of second comparison modules comprises a plurality of negative-channel metal-oxide-semiconductor (NMOS) transistors, a control end of each NMOS transistor is connected to a respective first test result, an input end of the NMOS transistor is connected to a first level, and an output end of the NMOS transistor is configured to output the second test result.

5. The circuit of claim 4, wherein each of the plurality of second comparison modules comprises a pre-charging module and the pre-charging module is configured to pre-charge the output end to a second level.

6. The circuit of claim 5, wherein the pre-charging module comprises an inverter and a positive-channel metal-oxide-semiconductor (PMOS) transistor; an output end of the inverter is connected to a control end of the PMOS transistor; an output end of the PMOS transistor is connected to the output end of the NMOS transistor; and an input end of the PMOS transistor is connected to the second level.

7. The circuit of claim 1, wherein the third comparison module comprises a NOT gate and a first SR latch; the first SR latch comprises a first NAND gate and a second NAND gate;
a first input end of the first NAND gate is configured to input the second test result, an output end of the first NAND gate is connected to the register apparatus and a second input end of the second NAND gate, a first input end of the second NAND gate is configured to input a control signal, and an output end of the second NAND gate is connected to a second input end of the first NAND gate.

8. The circuit of claim 1, wherein the third comparison module comprises a second SR latch; the second SR latch comprises a first NOR gate and a second NOR gate;
a first input end of the first NOR gate is configured to input the second test result, an output end of the first NOR gate is connected to the register apparatus and a second input end of the second NOR gate, a first input end of the second NOR gate is configured to input a control signal, and an output end of the second NOR gate is connected to a second input end of the first NOR gate.

9. A method for testing a memory chip, comprising:
reading word line data stored in all banks of a tested memory, wherein the word line data comprises a plurality of bit data;
performing a comparison test on each bit data in word line data stored in a tested word line, and outputting a first test result;
compressing first test results of all tested word lines in a bank into a second test result;
compressing second test results of all banks into an N-bit final test result, wherein N is a number of the banks of the tested memory; and
reading and saving the final test result.

10. The method of claim 9, further comprising:
acquiring reference data;
comparing each bit data in the word line data stored in the tested word line with the reference data; and
when any bit data in the word line data stored in the tested word line is different from the reference data, outputting an error level as the first test result.

11. The method of claim 9, further comprising:
pairwise comparing bit data, corresponding to different data input/output channels, in the word line data stored in the tested word line; and
when any two bit data in the word line data stored in the tested word line are different, outputting an error level as the first test result.

12. An electronic device, comprising a processor, and a memory having stored thereon a program or an instruction executable by the processor, wherein the program or the instruction, when being executed by the processor, causes the processor to implement steps of the method for testing a memory chip of claim 9.

13. A non-transitory computer-readable storage medium having stored thereon a program or an instruction that, when being executed by a processor of an electronic device, enables the electronic device to execute operations comprising:
reading word line data stored in all banks of a tested memory, wherein the word line data comprises a plurality of bit data;
performing a comparison test on each bit data in word line data stored in a tested word line, and outputting a first test result;
compressing first test results of all tested word lines in a bank into a second test result;
compressing second test results of all banks into an N-bit final test result, wherein N is a number of the banks of the tested memory; and
reading and saving the final test result.

14. The non-transitory computer-readable storage medium of claim 13, wherein the operations further comprise:
acquiring reference data;
comparing each bit data in the word line data stored in the tested word line with the reference data; and
when any bit data in the word line data stored in the tested word line is different from the reference data, outputting an error level as the first test result.

15. The non-transitory computer-readable storage medium of claim 13, wherein the operations further comprise:
pairwise comparing bit data, corresponding to different data input/output channels, in the word line data stored in the tested word line; and
when any two bit data in the word line data stored in the tested word line are different, outputting an error level as the first test result.
